(19) United States
(12) Patent Application Publication
(10) Pub. No.: US 2009/0024902 A1
(43) Pub. Date: Jan. 22, 2009

(54) MULTI-CHANNEL ERROR CORRECTION CODER ARCHITECTURE USING EMBEDDED MEMORY

(75) Inventors: Namphil JO, Hwaseong-si (KR); Kyuhyun SHIM, Suwon-si (KR); ChangII Son, Yongin-si (KR); Sungchung PARK, Daejeon (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/132,692

(22) Filed: Jun. 4, 2008

(30) Foreign Application Priority Data
Jun. 4, 2007 (KR) 10-2007-0054620

(51) Int. Cl. H03M 13/03; G06F 11/08

(52) U.S. Cl. 714/763; 714/E11.03

(57) ABSTRACT

A memory system includes a plurality of memory devices; and a memory controller having a plurality of communication channels for communicating data with the plurality of memory devices. The memory controller includes an error correction encoder that is adapted to encode data to be communicated from the memory controller via the plurality of communication channels, and/or an error correction decoder that is adapted to detect and correct errors in data communicated to the memory controller via the plurality of communication channels.

### CROSS-REFERENCES TO RELATED APPLICATIONS

This claims priority under 35 U.S.C. § 119 from Korean Patent Application 2007-0054620, filed on 4 Jun. 2007 in the names of Namphil Jo et al., the entirety of which is hereby incorporated by reference for all purposes as if fully set forth herein.

### BACKGROUND AND SUMMARY

1. Field

This invention pertains to the field of memory systems, and more particularly, to the field of memory systems employing error correction encoding.

2. Description

In some flash memory systems, a multi-channel error correction coder (ECC) architecture is employed with buffer memories for encoding/decoding the data from the host system to and from the flash memory.

FIG. 1 shows a block diagram of such a flash memory system 10. Flash memory system 10 includes a flash memory controller 100 and a memory block 200. Memory controller 100 includes a host interface 110, a user data buffer 120, a system data buffer 130, a NAND interface 140, and a central processing unit 150, all connected together by a system bus 160. NAND interface 140 includes a direct memory access (DMA) controller 144 and an error correction coder (ECC) block 145. ECC block 145 includes a plurality (N) of ECC modules, including ECC modules 141, 142 and 143. Memory block 200 includes a plurality (N) of NAND memory devices, including memory devices 211, 212 and 213. Connected between each of the ECC modules 141, 142 and 143 and a corresponding one of the memory devices 211, 212 and 213 is a channel 0, 1, N, etc.

FIG. 2 illustrates in greater detail interconnections between ECC block 145 and memory devices 211, 212 and 213 in flash memory system 10. As seen in FIG. 2, ECC module 141 includes encoder 161, and decoder block 165, which further comprises detector 162 and corrector 163. Likewise, ECC module 142: includes encoder 171, and decoder block 175, which further comprises detector 172 and corrector 173; and ECC module 143 includes encoder 181, and decoder block 185, which further comprises detector 182 and corrector 183.

In operation, data from a host device (e.g., a processor) destined to be stored in a memory device 211, for example, is sent by DMA controller 144 to ECC module 141. In ECC module 141, the data is first encoded by the encoder 161 and then transmitted to memory device 211 via channel 0. When data is to be read from memory device 211 and provided to a host device, it is first decoded by decoder 165 and then the decoded data is supplied to DMA controller 144. In decoder 165, detector 162 detects whether any errors are present in the data received from memory device 211, and if there are any errors, then corrector 163 corrects the errors.

FIG. 3 illustrates conventional decoding operations of one exemplary embodiment of a decoder block, such as decoder block 165 in ECC 141 in FIG. 2. Upon receiving data from memory device 211, a Bose-Chaudhuri-Hocquenghem (BCH) decoder (e.g., detector 162) calculates the syndrome to determine whether any errors are present in the received data. If the syndrome values are zero, then it is determined that the received data has no errors. Otherwise, a key equation solver (KES) block solves the key equation and a Chien search and error evaluator (CSEE) block determines the error values and error locations. Firmware (e.g., corrector 163) then corrects the errors as the data is read out of decoder block 165.

In a memory system having memory devices with low bit-density cells, the error rate in the device will be relatively low, and so the error detection and correction is not critical in view of the total system performance. However, in a memory system with memory devices using a high bit-density single-bit/cell structure, or having a multi-bit/cell structure, then the errors that occur in reading data from the memory devices are greater, requiring more detection and correction steps, and this reduces the read performance in the memory system.

Accordingly, it would be desirable to provide a memory system that can provide robust error detection and correction with an improved throughput. It would also be desirable to provide a memory system that can sustain a high read performance when using memory devices using a high bit-density single-bit/cell structure, or having a multi-bit/cell structure.

The present invention is directed to a memory system, and a multi-channel error correction coder architecture using embedded memory.

In one aspect of the invention, a memory system comprises: a plurality of memory devices; and a memory controller having a plurality of communication channels for communicating data with the plurality of memory devices, the memory controller comprising an error correction encoder that is adapted to encode data to be communicated from the memory controller via the plurality of communication channels.

In another aspect of the invention, a memory system comprises: a plurality of memory devices; and a memory controller having a plurality of communication channels for communicating data with the plurality of memory devices, the memory controller comprising an error correction decoder that is adapted to detect and correct errors in data communicated to the memory controller via the plurality of communication channels.

In yet another aspect of the invention, a method is provided in a memory system for processing data to be transmitted from a memory controller to a plurality of memory devices via a plurality of communication channels. The method comprises: storing in memory buffers data intended for the plurality of memory devices; encoding with a single encoder the data stored in the memory buffers intended for the plurality of memory devices; and sending the encoded data to the plurality of memory devices via the plurality of communication channels.

In still another aspect of the invention, a method is provided in a memory system for processing data to be transmitted from a memory controller to a plurality of memory devices via a plurality of communication channels. The method comprises: receiving data intended for the plurality of memory devices; encoding with a single encoder the received data intended for the plurality of memory devices; storing the encoded data intended for the plurality of memory devices in memory buffers; and sending the encoded data to the plurality of memory devices via the plurality of communication channels.

### BRIEF DESCRIPTION OF THE DRAWINGS

FIG. 1 shows a block diagram of a flash memory system.

FIG. 2 illustrates connections between an error correction coder (ECC) block and memory devices.

FIG. 3 illustrates conventional decoding operations of a flash memory decoder.

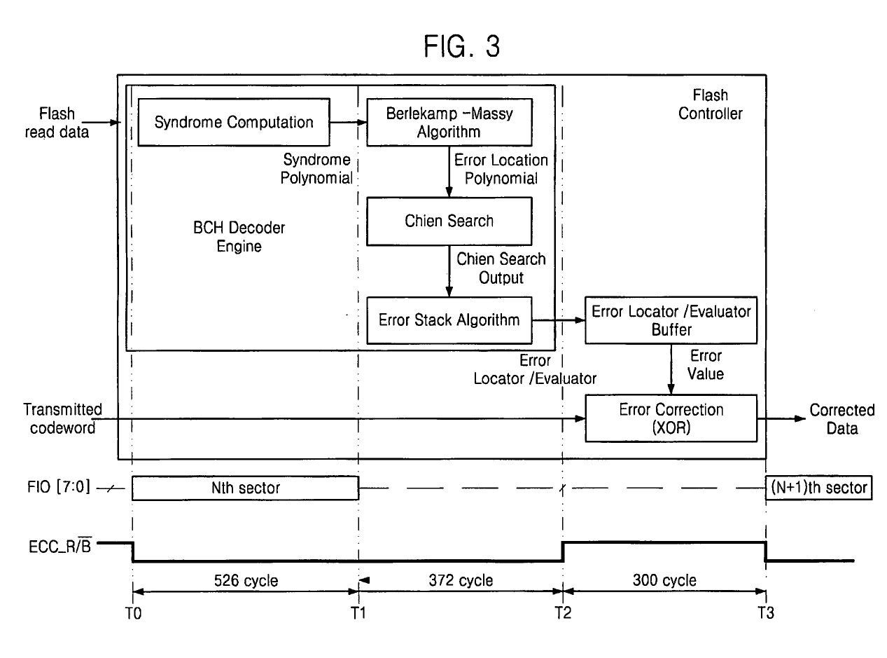

FIG. 4 illustrates a first embodiment of a memory system where an ECC is provided in internal buffer circuitry.

FIG. 5 illustrates one embodiment of a buffer controller that may be included in the memory system of FIG. 4.

FIG. 6 illustrates a second embodiment of a memory system where an ECC is provided in internal buffer circuitry.

FIG. 7 illustrates one embodiment of a buffer controller that may be included in the memory system of FIG. 6.

FIG. 8 illustrates a third embodiment of a memory system where an ECC is provided in internal buffer circuitry.

FIG. 9 illustrates one embodiment of a buffer controller that may be included in the memory system of FIG. 8.

FIG. 10 illustrates a fourth embodiment of a memory system where an ECC is provided in internal buffer circuitry.

FIG. 11 illustrates one embodiment of a buffer controller that may be included in the memory system of FIG. 10.

FIG. 12 illustrates decoding operations of a memory system where an ECC is provided in internal buffer circuitry.

FIG. 13 compares throughput versus sector error rate performance for the memory system of FIG. 1 against the performance of a memory system where the ECC is provided in internal buffer circuitry.

### DETAILED DESCRIPTION

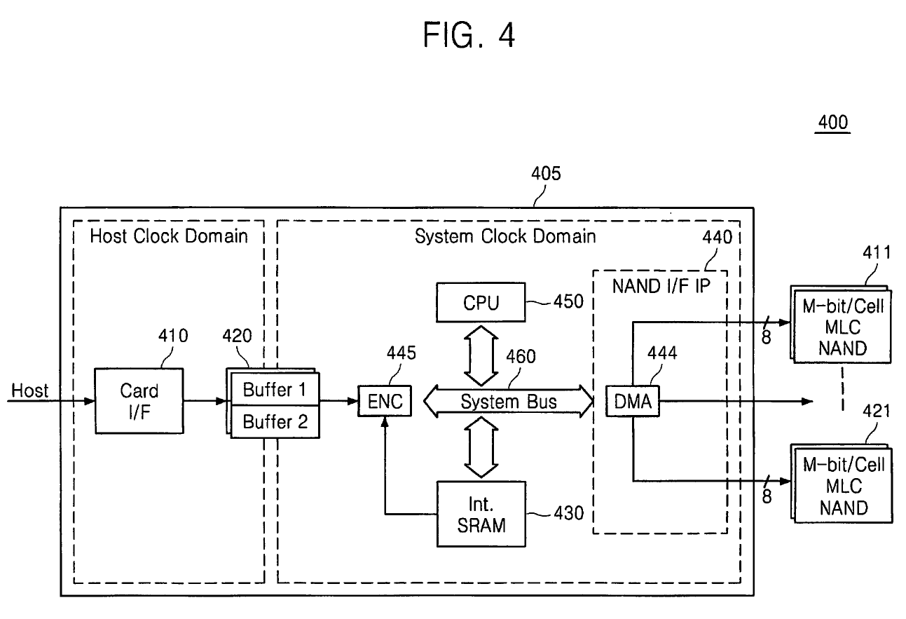

FIG. 4 illustrates a first embodiment of a memory system 400 where error correction coder (ECC) is provided in internal buffer circuitry. Memory system 400 includes a flash memory controller 405 and a memory block having a plurality (N) of NAND memory devices, including memory devices 411 and 421 and other memory devices not shown in FIG. 4. Memory controller 405 includes a host interface 410 and buffers 420. Memory controller 405 also includes a NAND interface 440, and a central processing unit 450, an error correction coder (ECC) block 445 and internal static random access memory (SRAM) 430 all connected together by a system bus 460. NAND interface 440 includes a direct memory access (DMA) controller 444 connected to each of the memory devices 411, 421. etc. via corresponding communication channels as illustrated in FIG. 4.

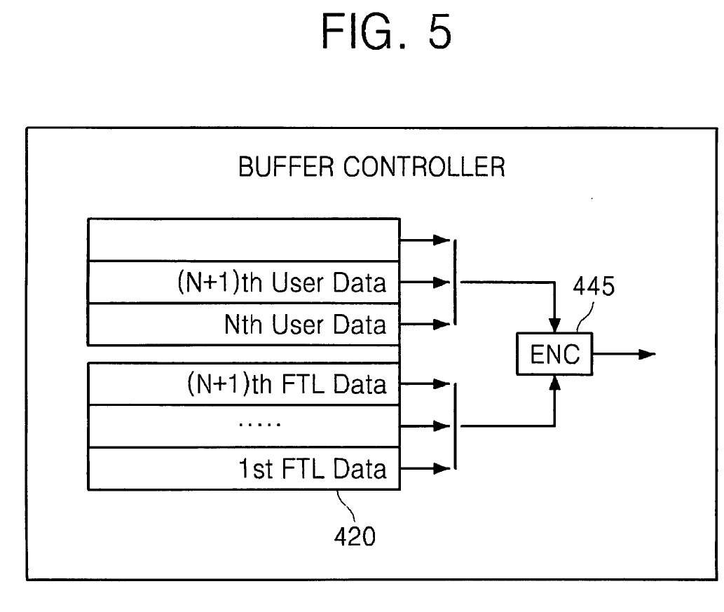

FIG. 5 illustrates one embodiment of a buffer controller that may be included in the memory system of FIG. 4. As shown in FIG. 5, buffers 420 include buffers for user data and buffers for Flash Translation Layer (FTL) data, all of which supply data to a same encoder 445. In the memory system 400, encoded parity values are stored in Special Function Register (SFR) memory and transmitted to NAND interface 440 via an external interface.

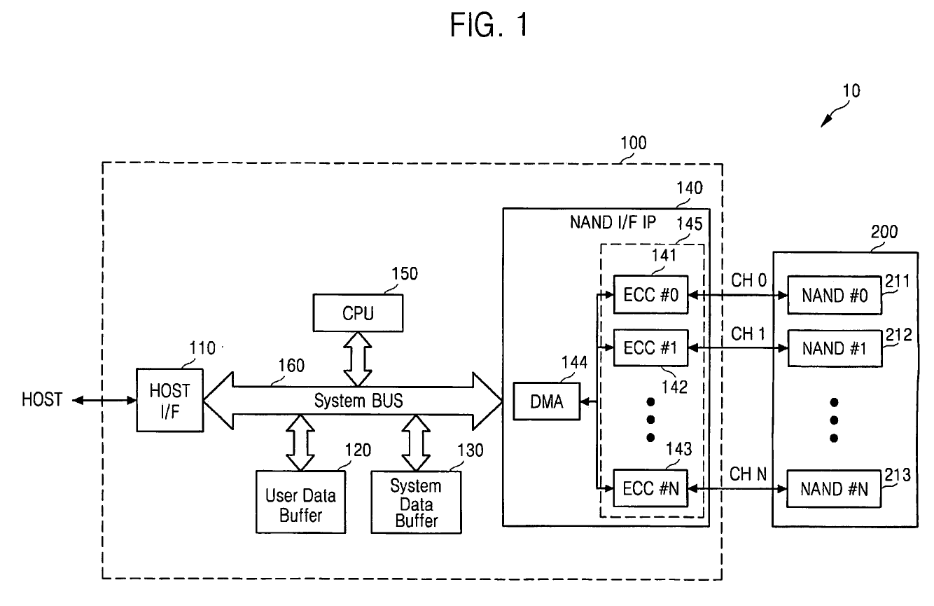

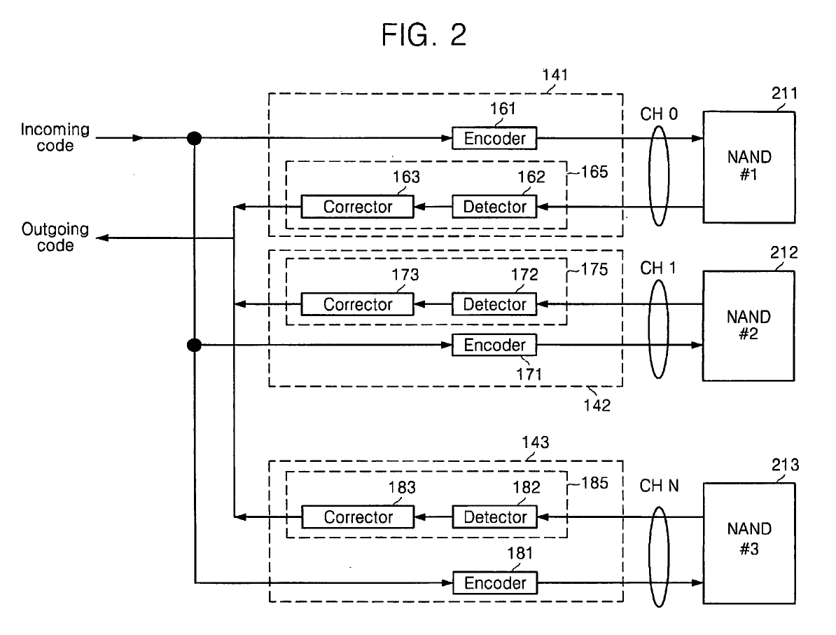

In the embodiment illustrated in FIGS. 4 and 5, an encoder 445 is placed in the buffer controller of memory controller 405. Advantageously, in contrast to the conventional arrangement illustrated in FIGS. 1 and 2 which includes separate ECCs for each communication channel, in the arrangement of FIGS. 4 and 5 a single ECC is provided for the user data buffer and FTL data buffer to supply encoded data to multiple communication channels for multiple memory devices.

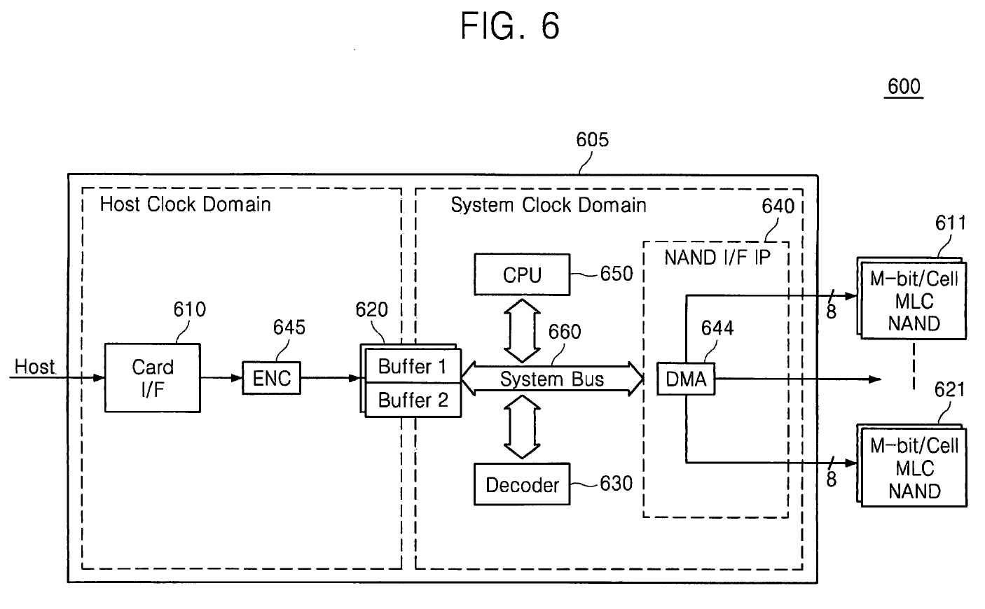

FIG. 6 illustrates a second embodiment of a memory system 600 where an ECC is provided in internal buffer circuitry. Memory system 600 includes a flash memory controller 605 and a memory block having a plurality (N) of NAND memory devices, including memory devices 611 and 621 and other memory devices not shown in FIG. 6. Memory controller 605 includes a host interface 610 and an error correction coder (ECC) block 645. Memory controller 605 also includes a NAND interface 640, and a central processing unit 650, buffers 620 and a decoder 630 all connected together by a system bus 660. NAND interface 640 includes a direct memory access (DMA) controller 644 connected to each of the memory devices 611, 621, etc. via corresponding communication channels as illustrated in FIG. 6.

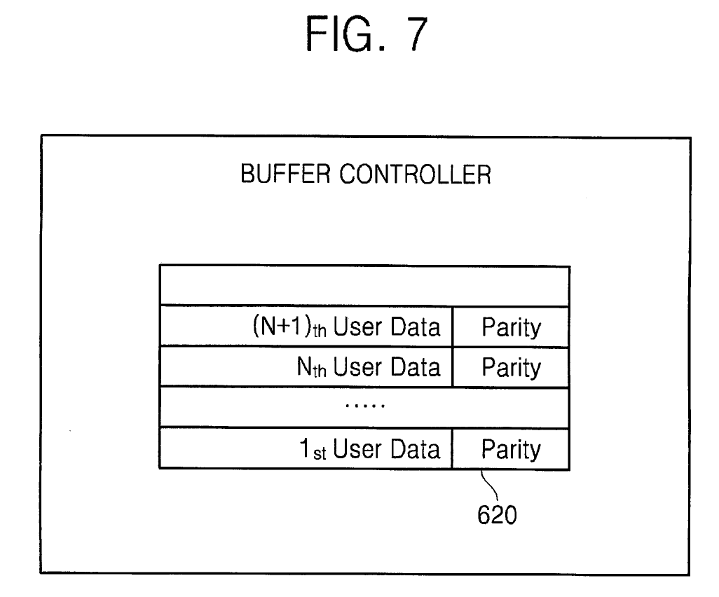

FIG. 7 illustrates one embodiment of a buffer controller that may be included in the memory system of FIG. 6. As shown in FIG. 7, encoder 645 encodes user data for multiple memory devices 611, 621, etc. and stores the encoded user data, including the parity bits, in buffers 620 from which it is communicated via DMA 644 to the multiple memory devices 611, 621, etc.

In the embodiment illustrated in FIGS. 6 and 7, an encoder 645 is placed in the buffer controller of memory controller 605. The encoder 645 is placed between the host interface and the buffers and encodes user data sent from the host to the memory system 600. Another encoder for FTL data is also available. Encoded data, including parity bits, are stored in the buffer memory. Also, only a single decoder is employed.

Advantageously, in contrast to the conventional arrangement illustrated in FIGS. 1 and 2 which includes separate ECCs for each communication channel, in the arrangement of FIGS. 6 and 7 a single ECC is provided for the user data supplied to all of the communication channels to all of the memory devices.

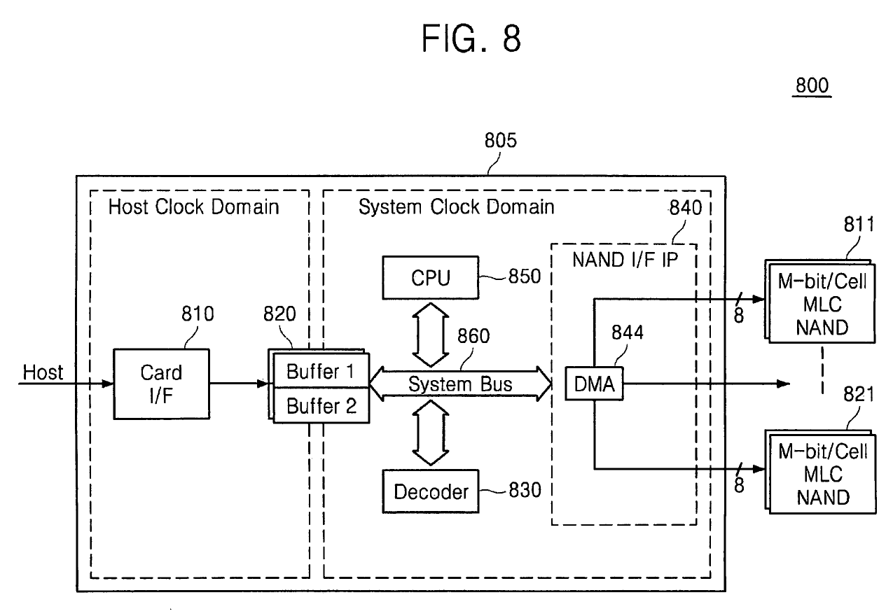

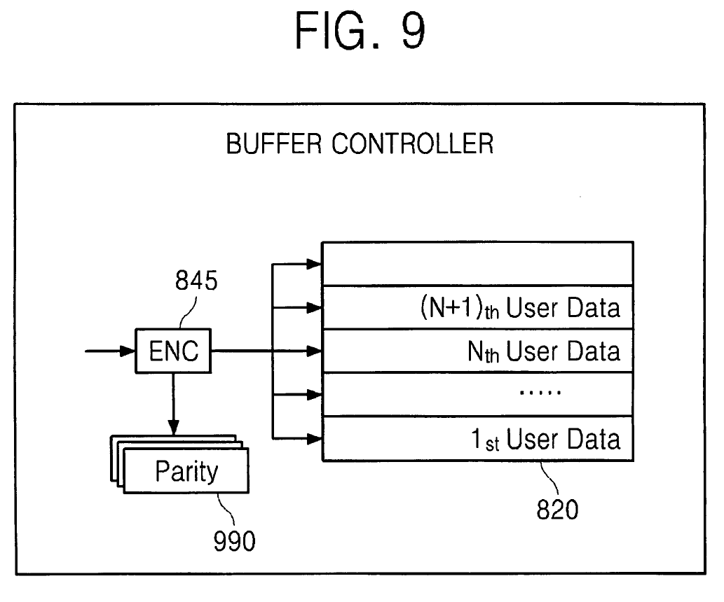

FIG. 8 illustrates a third embodiment of a memory system 800 where an ECC is provided in internal buffer circuitry. Memory system 800 includes a flash memory controller 805 and a memory block having a plurality (N) of NAND memory devices, including memory devices 811 and 821 and other memory devices not shown in FIG. 8. Memory controller 805 includes a host interface 810 and an error correction coder (ECC) block 845 (not shown in FIG. 8, but shown in FIG. 9). Memory controller 805 also includes a NAND interface 840, and a central processing unit 850, buffers 820 and a decoder 830 all connected together by a system bus 860. NAND interface 840 includes a direct memory access (DMA) controller 844 connected to each of the memory devices 811, 821, etc. via corresponding communication channels as illustrated in FIG. 8.

FIG. 9 illustrates one embodiment of a buffer controller that may be included in the memory system of FIG. 8. As shown in FIG. 9, encoder 845 stores encoded user data in buffers 820, and stores parity bits separately in a register 990 of the buffer controller.

In the embodiment illustrated in FIGS. 8 and 9, an encoder 845 is placed in the buffer controller of memory controller 805. The encoder 845 is placed between the host interface and the buffers and encodes user data from the host to the memory system. Another encoder for FTL data is also available. Encoded data is stored in the buffer memory, and parity bits are stored separately in a register of the buffer controller. Meanwhile, only a single decoder is used.

Advantageously, in contrast to the conventional arrangement illustrated in FIGS. 1 and 2 which includes separate ECCs for each communication channel, in the arrangement of FIGS. 8 and 9 a single ECC is provided for the user data supplied via multiple communication channels to multiple memory devices.

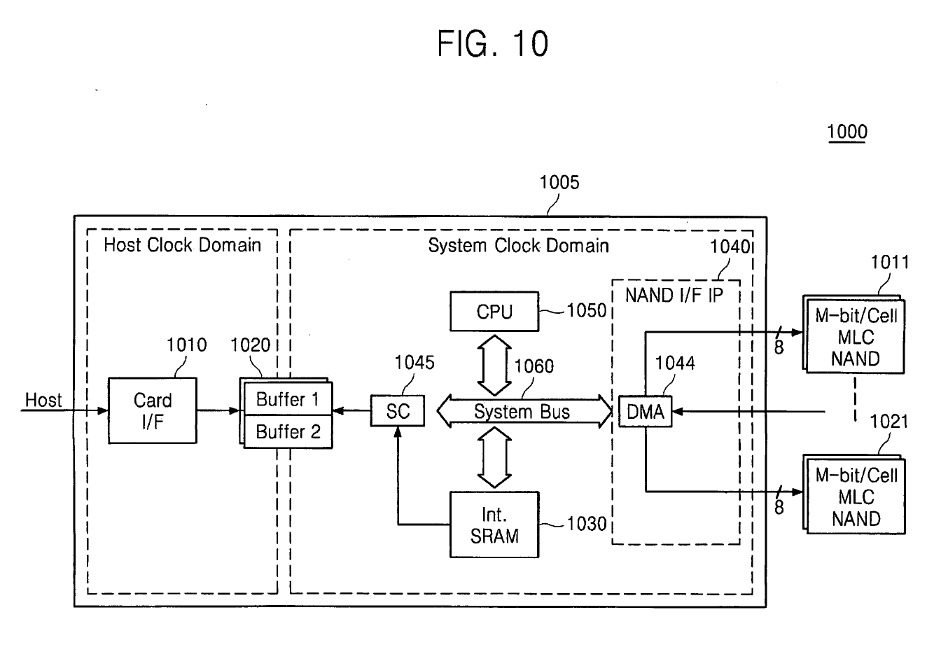

FIG. 10 illustrates a fourth embodiment of a memory system 1000 where an ECC is provided in internal buffer circuitry. Memory system 1000 includes a flash memory controller 1005 and a memory block having a plurality (N) of NAND memory devices, including memory devices 1011 and 1021 and other memory devices not shown in FIG. 10. Memory controller 1005 includes a host interface 1010 and buffers 1020. Memory controller 1005 also includes a NAND interface 1040, and a central processing unit 1050, syndrome calculation (SC) block 1045 and internal static random access memory (SRAM) 1030 all connected together by a system bus 1060. NAND interface 1040 includes a direct memory access (DMA) controller 1044 connected to each of the memory devices 1011, 1021, etc. via corresponding communication channels as illustrated in FIG. 10.

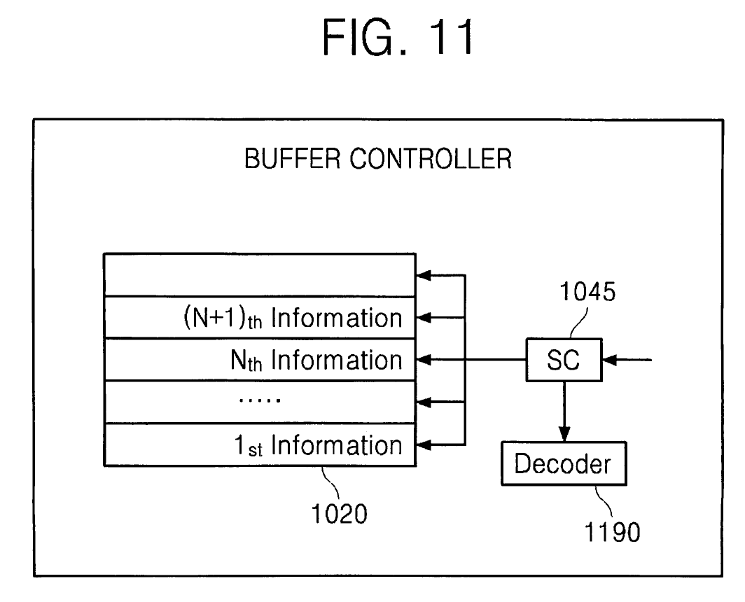

FIG. 11 illustrates one embodiment of a buffer controller that may be included in the memory system of FIG. 10. As shown in FIG. 11, a syndrome calculation (SC) block 1045 calculates syndrome values using data transmitted from the memory devices. When an error occurs, decoder 1190 corrects the error(s).

In the embodiment illustrated in FIGS. 10 and 11, a syndrome calculation (SC) block 1045 and a decoder 1190 are placed in the buffer controller of memory controller 1005. The error detection process is performed in conjunction with data transfer to the buffer memory using DMA with an interleave mode. SC block 1045 calculates syndrome values, and when an error occurs, a pipelined mode is employed by decoder 1190 to correct the error(s).

Advantageously, in contrast to the conventional arrangement illustrated in FIGS. 1 and 2 which includes separate syndrome calculators and decoders for each communication channel, in the arrangement of FIGS. 10 and 11 a single ECC is provided for multiple data retrieved via multiple communication channels from multiple memory devices.

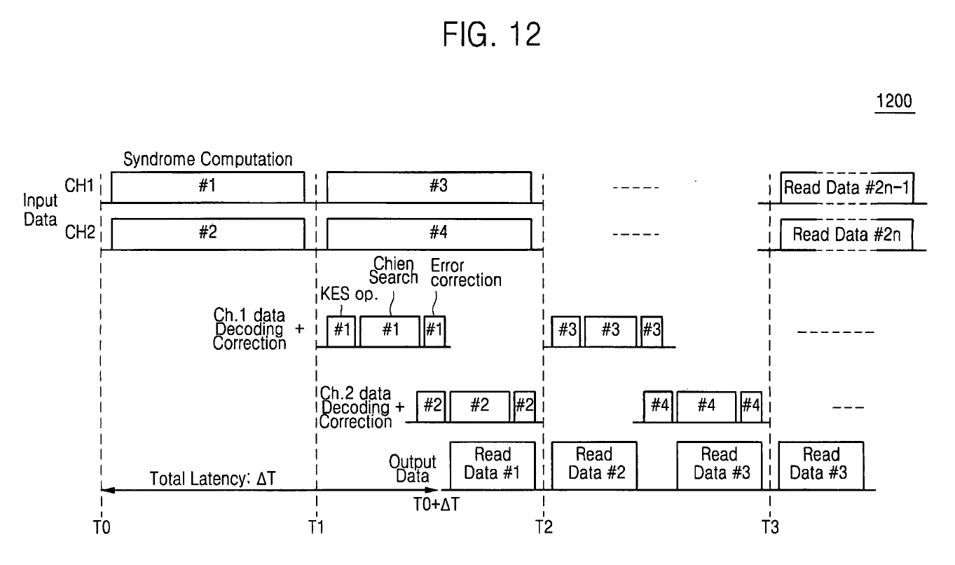

FIG. 12 illustrates decoding operations of a memory system where an ECC is provided in internal buffer circuitry.

In the time period from T0 to T1, data is transmitted simultaneously through two channels from memory devices to the buffer memories, and syndrome values are calculated simultaneously. First and second buffers read data at the same time and if the channels have any errors, then the operation proceeds to the error correction step. In the time period from T1 to T2, the decoder block is operated in a pipeline mode using a single decoder and a plurality of buffers, so it calculates error locations with a first channel's syndrome value first and continuously calculates the second channel's error locations. A buffer stores read data for calculating the syndrome value, a buffer stores data during the decoding process for calculating the error locations and pattern, and a buffer stores corrected data for transmission to the host. In the time period from T2 to T3, the process continues and repeats, now outputting data from two channels during a same period where subsequent data for two channels is input to be detected and decoded in the following frame.

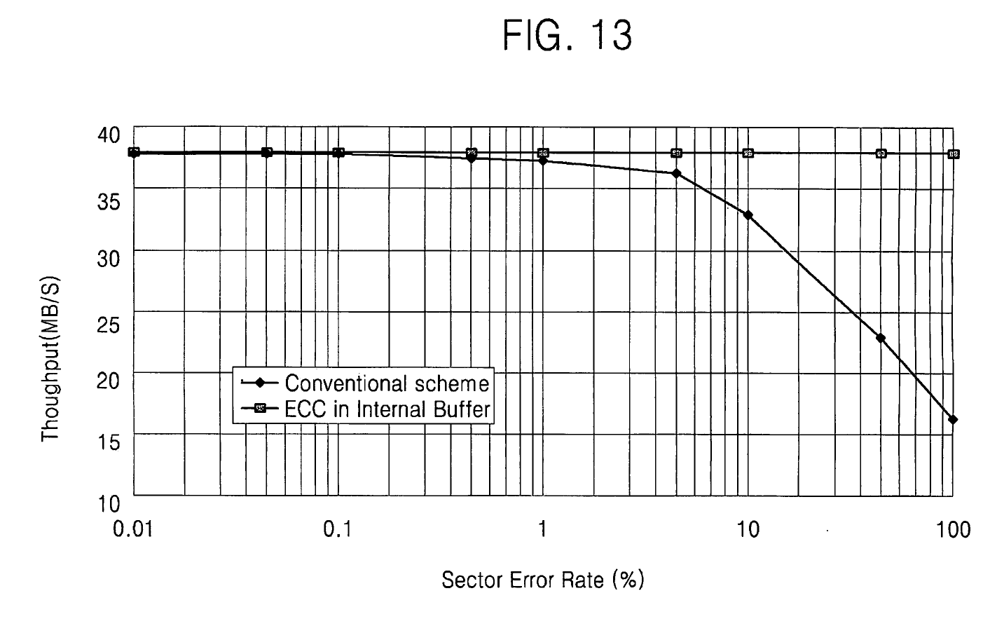

FIG. 13 compares throughput versus sector error rate performance for the memory system of FIG. 1 against the performance of a memory system where the ECC is provided in internal buffer circuitry. It can be seen from FIG. 13 that the memory system where the ECC is provided in internal buffer circuitry exhibits increased throughput performance in cases where there is a high memory sector error rate.

While preferred embodiments are disclosed herein, many variations are possible which remain within the concept and scope of the invention. Such variations would become clear to one of ordinary skill in the art after inspection of the specification, drawings and claims herein. The invention therefore is not to be restricted except within the spirit and scope of the appended claims.

We claim:

1. A memory system, comprising:
a plurality of memory devices; and
a memory controller having a plurality of communication channels for communicating data with the plurality of memory devices, the memory controller comprising an error correction encoder that is adapted to encode data to be communicated from the memory controller via the plurality of communication channels.

2. The memory system of claim 1, wherein the memory controller further comprises:
a plurality of memory buffers for staging data either before or after it is encoded by the error correction encoder; and
a buffer controller for controlling access to the plurality of memory buffers.

3. The memory system of claim 2, wherein the memory buffers are adapted to store data prior to encoding by the error correction encoder.

4. The memory system of claim 3, wherein the memory controller further comprises an SRAM adapted to store internal system data for the memory system, wherein the encoder is adapted to encode the internal system data for the plurality of communication channels.

5. The memory system of claim 3, wherein the memory controller further comprises a parity register for storing parity bits for the encoded data.

6. The memory system of claim 3, wherein the memory controller further comprises a direct memory access (DMA) controller adapted to communicate the encoded data to the plurality of memory devices over the plurality of communication channels.

7. The memory system of claim 3, wherein the memory controller further comprises an error decoder for error detection and correction of data received by the memory controller from the plurality of memory devices over the plurality of communication channels.

8. The memory system of claim 2, wherein the memory buffers are adapted to store the encoded data and parity bits for the encoded data.

9. The memory system of claim 8, wherein the memory controller further comprises:
an SRAM adapted to store internal system data for the memory system; and
a second encoder adapted to encode the internal system data for the plurality of communication channels.

10. The memory system of claim 8, wherein the memory controller further comprises an error decoder for error detection and correction of data received by the memory controller from the plurality of memory devices over the plurality of communication channels.

11. The memory system of claim 8, wherein the memory controller further comprises a direct memory access (DMA) controller adapted to communicate the encoded data to the plurality of memory devices over the plurality of communication channels.

12. The memory system of claim 2, wherein the memory buffers are adapted to store the encoded data, and wherein the memory controller further comprises a parity register for storing parity bits for the encoded data.

13. The memory system of claim 12, wherein the memory controller further comprises:
an SRAM adapted to store internal system data for the memory system; and
a second encoder adapted to encode the internal system data for the plurality of communication channels.

14. The memory system of claim 12, wherein the memory controller further comprises an error decoder for error detection and correction of data received by the memory controller from the plurality of memory devices over the plurality of communication channels.

15. The memory system of claim 12, wherein the memory controller further comprises a direct memory access (DMA) controller adapted to communicate the encoded data to the plurality of memory devices over the plurality of communication channels.

16. The memory system of claim 1, wherein the memory controller further comprises:
an error detector adapted to detect errors in data received by the memory controller via the plurality of communication channels;
a plurality of memory buffers for staging error detection information from the error detector for a plurality of data sets; and
an error location identifier for determining error locations within the data sets using the error detection information.

17. The memory system of claim 16, wherein the memory controller further comprises a direct memory access (DMA) controller adapted to communicate the received data from the plurality of communication channels to the error detector.

18. A memory system, comprising:
a plurality of memory devices; and
a memory controller having a plurality of communication channels for communicating data with the plurality of memory devices, the memory controller comprising an error correction decoder that is adapted to detect and correct errors in data communicated to the memory controller via the plurality of communication channels.

19. The memory system of claim 18, wherein the memory controller further comprises a direct memory access (DMA) controller adapted to communicate the data from the plurality of communication channels to the error correction decoder.

20. In a memory system, a method of processing data to be transmitted from a memory controller to a plurality of memory devices via a plurality of communication channels, the method comprising:
storing in memory buffers data intended for the plurality of memory devices;
encoding with a single encoder the data stored in the memory buffers intended for the plurality of memory devices; and
sending the encoded data to the plurality of memory devices via the plurality of communication channels.

21. The method of claim 20, sending the encoded data to the plurality of memory devices via the plurality of communication channels comprises sending the encoded data to the plurality of memory devices with a direct memory access (DMA) controller.

22. The method of claim 20, further comprising employing a single error correction decoder to correct errors in data received by the memory controller from the plurality of memory devices over the plurality of communication channels.

23. In a memory system, a method of processing data to be transmitted from a memory controller to a plurality of memory devices via a plurality of communication channels, the method comprising:
receiving data intended for the plurality of memory devices;
encoding with a single encoder the received data intended for the plurality of memory devices;
storing the encoded data intended for the plurality of memory devices in memory buffers; and
sending the encoded data to the plurality of memory devices via the plurality of communication channels.

24. The method of claim 23, sending the encoded data to the plurality of memory devices via the plurality of communication channels comprises sending the encoded data to the plurality of memory devices with a direct memory access (DMA) controller.

25. The method of claim 23, further comprising employing a single error correction decoder to correct errors in data received by the memory controller from the plurality of memory devices over the plurality of communication channels.
